(19) United States
(12) Patent Application Publication
(10) Pub. No.: US 2011/0304960 A1
(43) Pub. Date: Dec. 15, 2011

(54) RETAINING APPARATUS FOR DATA STORAGE DEVICE

(75) Inventor: WEN-HU LU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 12/887,234

(22) Filed: Sep. 21, 2010

(30) Foreign Application Priority Data
Jun. 14, 2010 (CN) 201010200699.8

(51) Int. Cl. H05K 7/00; F16M 13/00

(52) U.S. Cl. 361/679.01; 248/316.5

(57) ABSTRACT

A retaining apparatus used for a data storage device includes a tray and a retaining device. The tray is for receiving the data storage device. The retaining device includes a base member, an arm member and a locking member. The base member attaches to the tray. The arm member pivotally attaches to the base member. A retaining portion and a protrusion are located at opposite distal end of the arm member. A locking member pivotably attaches to the base member to block the arm member. The arm member rotates relative to the base member from a locked position to an unlocked position. In the locked position, the retaining portion protrudes from the base member and the locking member blocks the protrusion. In the unlocked position, the locking member disengages from the locking portion, and the retaining portion resides in the base member.

### CROSS-REFERENCE TO RELATED APPLICATION

This application is related to co-pending U.S. patent application entitled “RETAINING APPARATUS FOR DATA STORAGE DEVICES”, application Ser. No. 12/532,349, Application date Aug. 17, 2009, Attorney Docket number US25911.

### BACKGROUND

1. Technical Field

The disclosure generally relates to a retaining apparatus for data storage devices, especially to a retaining apparatus with a tray for receiving and retaining at least one data storage device.

2. Description of Related Art

Typically, a data storage device, such as a hard disk drive is screwed to a computer enclosure. Vibration of the data storage device during use may cause the screws to come loose resulting in greater vibration and erroneous data read from or written to the data storage device. Therefore there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a partial, exploded, and isometric view of a retaining apparatus according to an embodiment.

FIG. 2 is similar to FIG. 1, but shown in another aspect.

FIG. 3 is an assembled view of FIG. 1.

FIG. 4 is a sectional view of FIG. 3.

FIG. 5 is an assembled view of FIG. 1 with an arm member positioned oblique to a base member.

FIG. 6 is a sectional view of FIG. 5.

FIG. 7 is an assembled view of a data storage device, a retaining apparatus and a bracket.

FIG. 8 is similar to FIG. 7, but shows another working state of the retaining apparatus.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

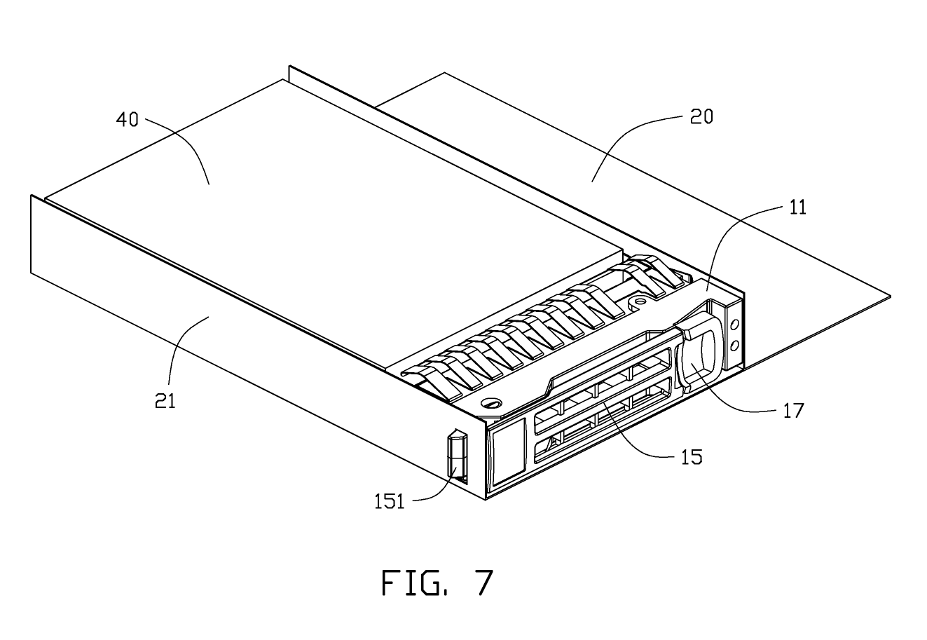

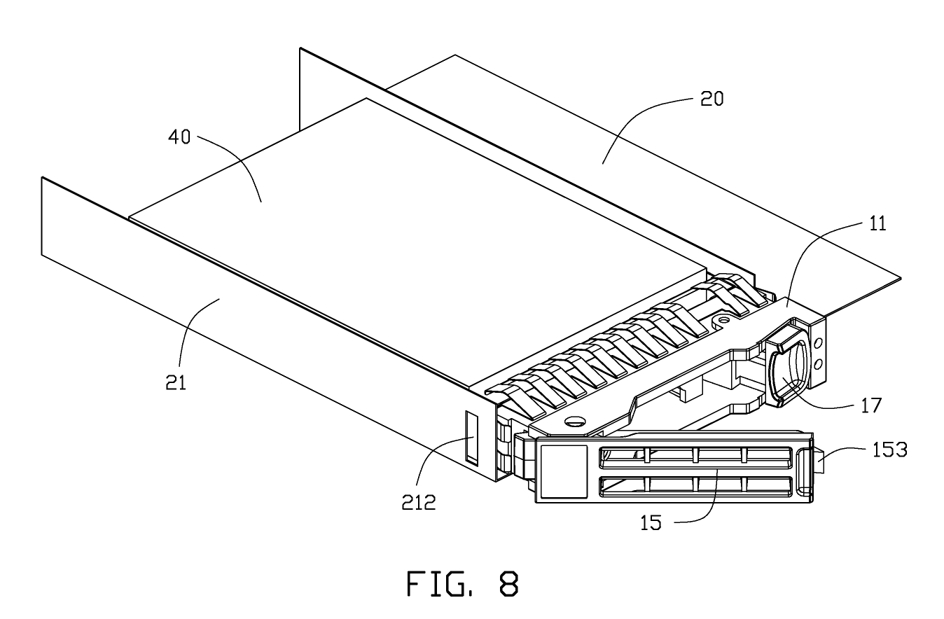

Referring to FIG. 7 and FIG. 8, a bracket 20 is used in an electronic device for mounting at least one retaining apparatus for data storage device 40. The bracket 20 includes two substantially parallel side plates 21. A slideway is defined between the two side plates 21 for receiving the retaining apparatus. One of the side plates 21 defines a rectangular retaining opening 212.

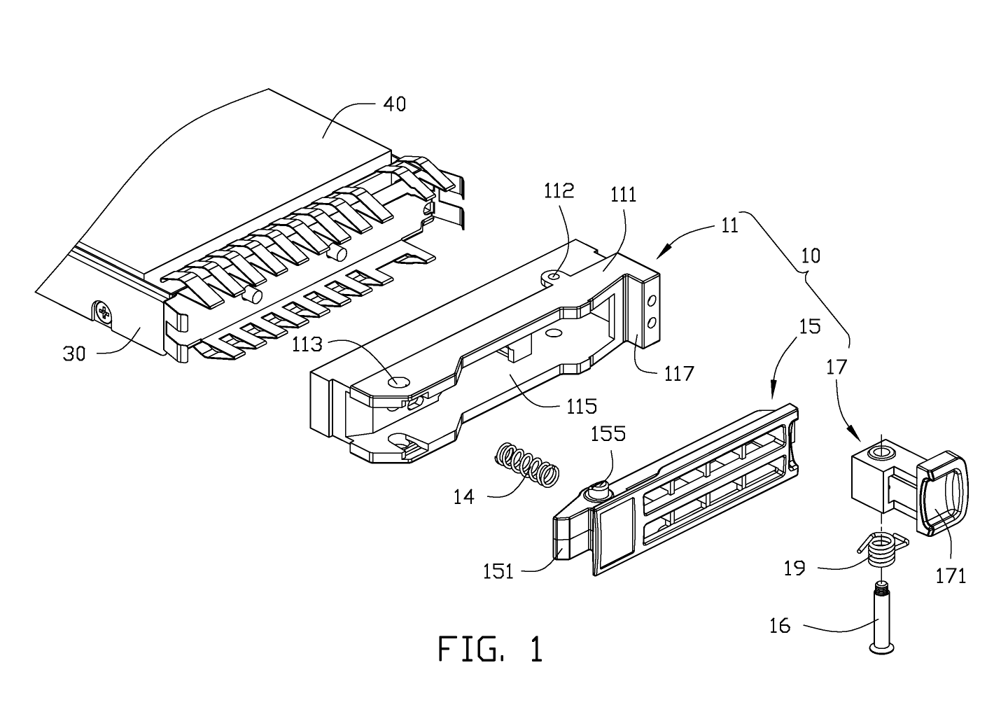

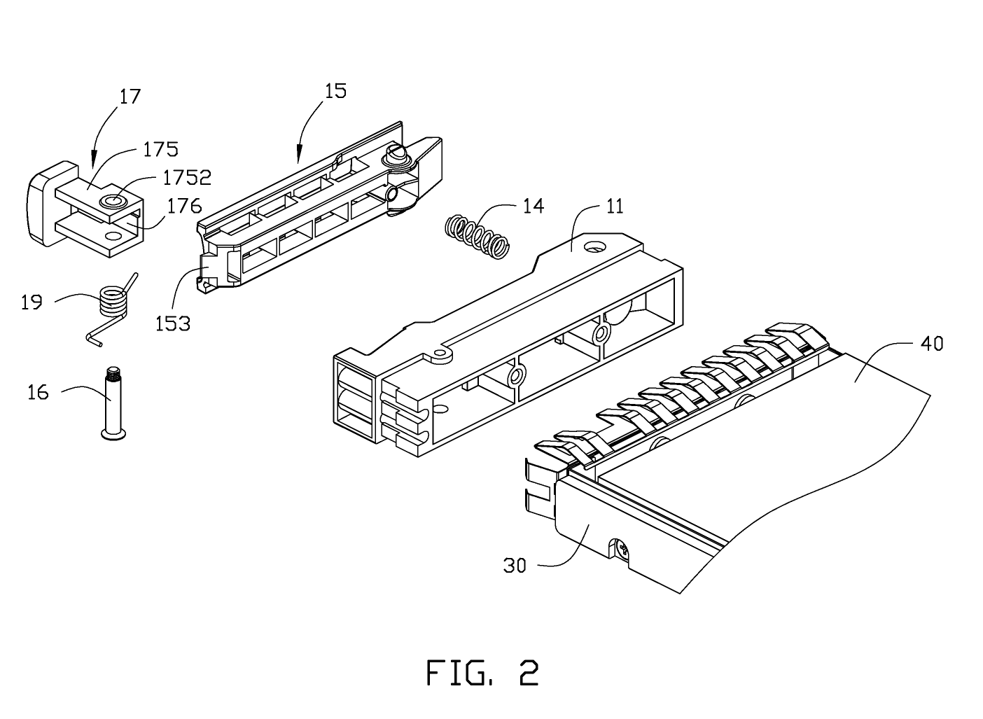

Referring to FIG. 1 and FIG. 2, each retaining apparatus includes a tray 30 and a retaining device 10.

The retaining device 10 includes a base member 11, an arm member 15, and a locking member 17.

Two pairs of pivot holes 113 and 112 are defined in the base member 11 for receiving the arm member 15 and the locking member 17. The base member 11 includes a pair of retaining walls 111, and a sidewall 117. A receiving space 115 is enclosed by the retaining walls 111 and the sidewall 117 for receiving the arm member 15.

The arm member 15 has an oblong configuration. The arm member 15 has a retaining member 151 corresponding to the retaining opening 212 and a tapered protrusion 153 for positioning the arm member 15. The retaining member 151 and the protrusion 153 are placed at opposite distal ends of the arm member 15. A coil spring 14 is located between the base member 11 and the arm member 15 to provide an ejection force to the arm member 15 to rotate the arm member 15 away from the base member 11. Two pivot portions 155 are located on opposite sides of the arm member 15 corresponding to the pivot hole 113.

The locking member 17 is pivotably attached to the base member 11. The locking member 17 can block the protrusion 153 of the arm member 15. The locking member 17 includes an operating portion 171, two substantially parallel connecting walls 175 and a blocking wall 176 substantially perpendicular to the connecting walls 175. A recess is defined in the operating portion 171 to facilitate the operation of the locking member 17. A pair of pivot holes 1752 is defined in the connecting walls 175. A post 16 and a coil spring 19 are provided to pivotably attach the locking member 17 to the base member 11 and keep the locking member 17 in a locking position. The coil spring 19 is clasped between the base member 11 and the locking member 17.

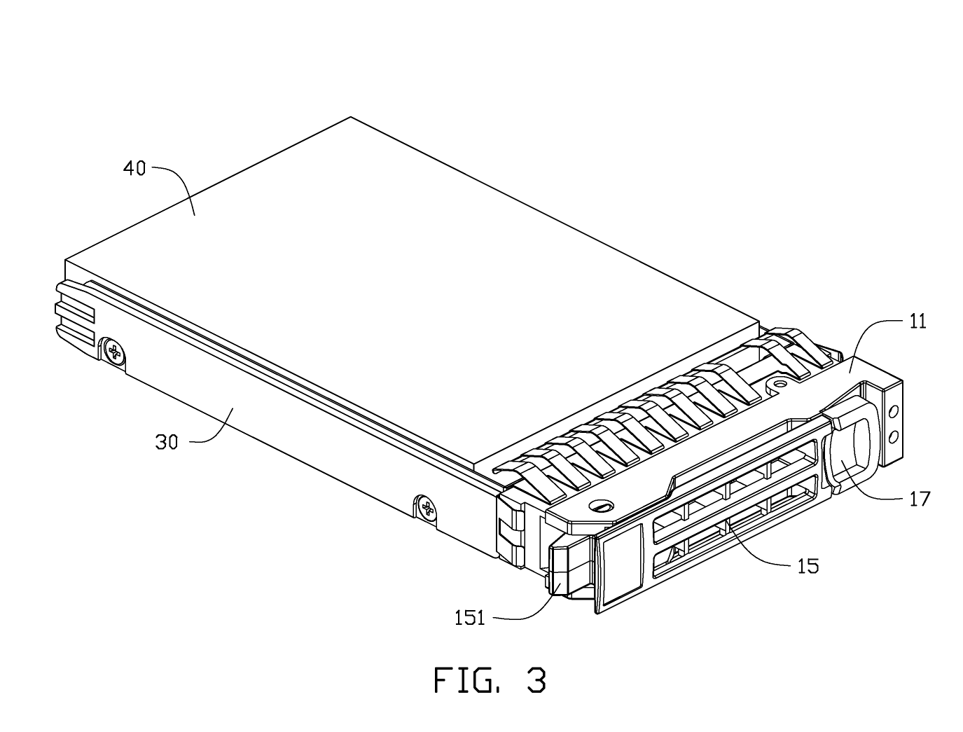

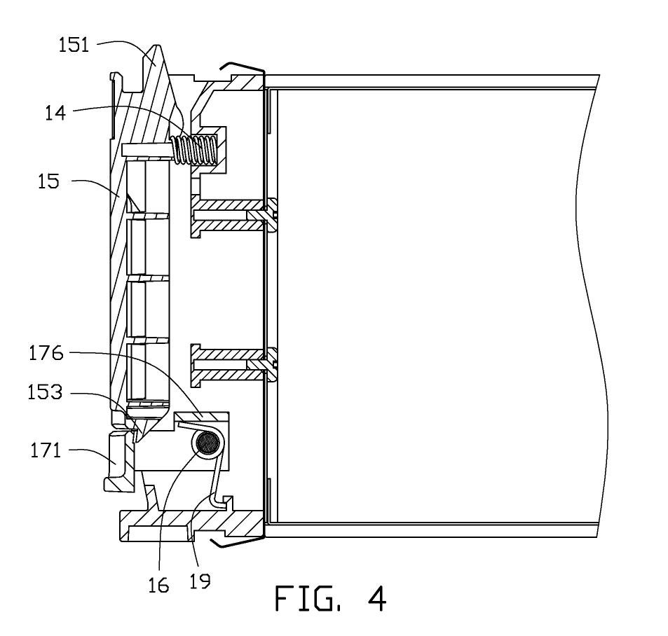

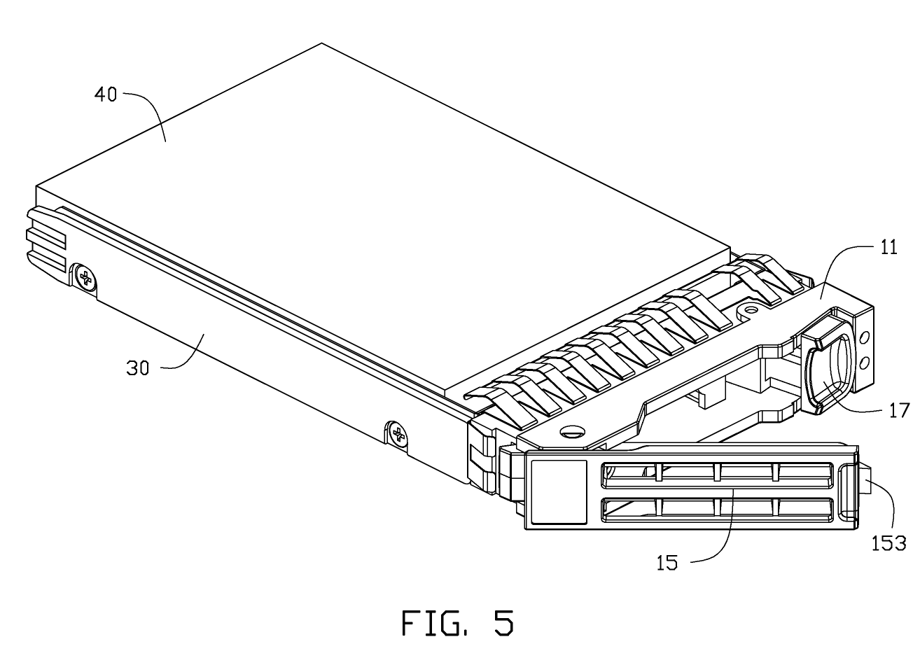

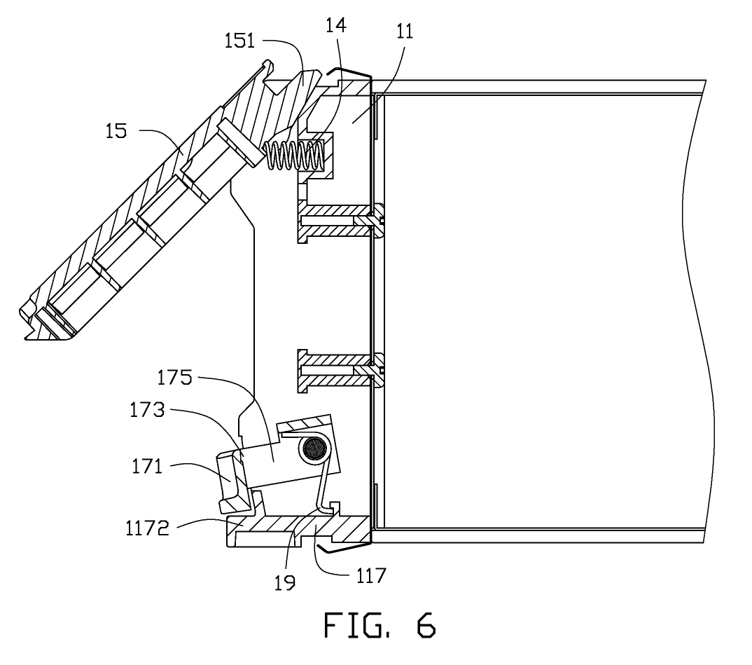

Referring to FIG. 3 through FIG. 6, during assembling of the retaining member 10, the base member 11 is fixed to the tray 30. The arm member 15 is pivotably fixed to the base member 11 about a first pivot axis with the pivot portions 155 extending through the pivot holes 113. The coil spring 14 is placed between the base member 11 and the arm member 15. The locking member 17 is pivotably attached to the base member 11 about the post 16, and the coil spring 19 is around the post 16 and is mounted between the base member 11 and locking member 17.

Referring to FIG. 7 and FIG. 8, when mounting the retaining apparatus into the bracket 20, the arm member 15 is angled from the base member 11. The tray 30, with the retaining device 10 is completely slid into the slideway of the bracket 20. Then the arm member 15 is rotated towards the base member 40, thus the retaining portion 151 gradually engages with the side wall 21 through the retaining opening 212. When the protrusion 153 of the arm member 15 reaches the base member 11, the protrusion 153 pushes the locking member 17 to rotate sideways. The locking member 17 rotates back to the original position and blocks the arm member 15 from rotating outward when the arm member 15 rotates substantially parallel to the base member 11. The coil spring 14 is compressed. The retaining apparatus is then mounted to the bracket 20.

When removing the retaining apparatus from the bracket 20, the operating portion 171 of the locking member 17 is pivoted about the post 16 and away from arm member 15 in a direction that is approximately a longitudinal direction of arm member 15. When the operating portion of locking member 15 is no longer blocking the protrusion 153 of the arm member 15, the arm member 15 rotates outward due to the resilient force of the spring 14. The retaining portion 151 is disengaged from the retaining opening 212. The retaining apparatus can then be moved out of the bracket 20.

It is also to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A retaining apparatus for a data storage device, comprising:
a tray for receiving the data storage device; and
a retaining device, comprising:
a base member attached to the tray;
an arm member pivotally attached to the base member, a retaining portion and a protrusion located at opposite distal end of the arm member; and
a locking member pivotably attached to the base member to block the arm member;
wherein the arm member is rotatably relative to the base member from a locked position, where the retaining portion protrudes from the base member and the protrusion is blocked by the locking member, to an unlocked position, where the locking member is disengaged from the locking portion and the retaining portion resides in the base member.

2. The retaining apparatus of the claim 1, wherein a receiving space is defined in the base member for receiving the arm member.

3. The retaining apparatus of the claim 1, wherein an coil spring is located between the base member and the arm member to provide an ejection force to the arm member to rotate the arm member away from the base member.

4. The retaining apparatus of the claim 1, wherein the locking member comprising an operating portion, and a recess is defined in the operating portion to facilitate operation of the locking member.

5. The retaining apparatus of the claim 1, wherein the locking member is rotated about a post, a coil spring is around the post and is clasped between the base member and the locking member.

6. The retaining apparatus of the claim 1, wherein the protrusion is tapered.

7. The retaining apparatus of the claim 1, wherein the arm member has an oblong configuration.

8. The retaining apparatus of the claim 1, wherein the arm member pivots about a first axis, and the locking member pivots about a second axis, and the second axis is substantially parallel to the first axis.

9. An electronic device, comprising:
a bracket; and
a retaining apparatus for receiving a data storage device, the retaining apparatus comprising:
a tray for receiving the data storage device; and
a retaining device, comprising:
a base member attached to the tray;
an arm member pivotally attached to the base member, a retaining portion and a protrusion located at opposite distal end of the arm member; and
a locking member pivotably attached to the base member to block the arm member;
wherein the arm member is rotatably relative to the base member from a locked position, where the retaining portion protrudes from the base member and is engaged with the bracket, and the protrusion is blocked by the locking member, to an unlocked position, where the locking member is disengaged from the locking portion and the retaining portion is disengaged from the bracket.

10. The electronic device of the claim 9, wherein a receiving space is defined in the base member for receiving the arm member.

11. The electronic device of the claim 9, wherein an coil spring is located between the base member and the arm member to provide an ejection force to the arm member to rotate the arm member away from the base member.

12. The electronic device of the claim 9, wherein the locking member comprising an operating portion, and a recess is defined in the operating portion to facilitate operation of the locking member.

13. The electronic device of the claim 9, wherein the locking member is rotated about a post, a coil spring is around the post and is clasped between the base member and the locking member.

14. The electronic device of the claim 9, wherein the protrusion is tapered.

15. The electronic device of the claim 9, wherein the arm member has an oblong configuration.

16. The electronic device of the claim 9, wherein the arm member pivots about a first axis, and the locking member pivots about a second axis, and the second axis is substantially parallel to the first axis.
